(19) United States
(12) Patent Application Publication
(10) Pub. No.: US 2013/0276852 A1
(43) Pub. Date: Oct. 24, 2013

(54) STRUCTURAL ELEMENT FOR GENERATING THERMOELECTRIC POWER AND METHOD FOR THE PRODUCTION THEREOF

(71) Applicant: Jehad Aiysh, Hagen (DE)

(72) Inventor: Jehad Aiysh, Hagen (DE)

(21) Appl. No.: 13/976,124

(22) PCT Filed: Dec. 7, 2011
(86) PCT No.: PCT/EP11/06139

§ 371 Date: Jun. 26, 2013

(30) Foreign Application Priority Data
Dec. 27, 2010 (DE) 20 2010 016 971.2

(51) Int. Cl. H01L 35/28

(52) U.S. Cl. CPC H01L 35/28; H01L 35/34
USPC 136/205; 427/58; 427/126.4; 136/201

(57) ABSTRACT

The invention relates to a thermoelectric structural element (9) for generating thermoelectric power that is formed by at least two layers (1, 2) and two metallic electrical contacts (4, 5). The layers (1, 2) contain mixtures primarily of chalk and quartz sand, with the layers (1, 2) comprising different mixtures. Using different thicknesses of the metallic electrical contacts (4, 5) and the layers (1, 2), the thermoelectric structural element (9) can be produced, inter alia, as a facade panelling, masonry wall element or wallpaper. The invention also relates to a method for producing a thermoelectric structural element (9).

The invention relates to a thermoelectric component and to a method for the production of a thermoelectric component.

Because of the increasing demand for electricity and the finite amount of fossil fuels, and because of the need to reduce CO₂ emissions, there is a need for obtaining energy from renewable energy sources. Aside from wind and water power, natural heat from the energy of the sun and thermal sources as well as industrial waste heat offer themselves as possibilities. The conversion of heat energy to thermoelectric current has been known as the Seebeck effect for a long time.

Temperature differences between two metals are utilized in the generation of thermoelectric current. Generation of the thermoelectric current is based on the principle that charge carriers regroup under the influence of a temperature difference. Because of the rearrangement, an electric voltage occurs at the contacts of the two metals, if a temperature difference between the contacts prevails. This phenomenon is used in thermoelectric elements (called TEs) and thermoelectric generators (called TEGs), for example.

In past years, numerous publications were made describing different methods and apparatuses for obtaining thermoelectric current. Almost all of these publications were based on semiconductor technology. Examples of this are known, among other things, from DE 102 31 445 A1, DE 102 30 080 A1, DE 102 32 445 A1, U.S. Pat. No. 6,300,150 31, and U.S. Pat. No. 6,396,191 B1.

Furthermore, many publications exist with regard to the different possibilities of use of conventional thermoelectric elements. Examples of use are known, among other things, from DE 101 24 623 A1, DE 199 46 806 A1, NL 1 020 485 C2, and WO 2009/030236 A2. Because of their low degree of effectiveness and their high production costs, conventional thermoelectric elements are currently uneconomical, and their use has been restricted to only a few areas until now. In order to achieve a better quality figure, research is currently being done on thermoelectric generators with nanostructures, but this is very complicated and therefore expensive.

A general disadvantage of the known thermoelectric elements or generators is that an apparatus for being able to affix the conventional thermoelectric elements to walls or on free surfaces is required, in each instance, to generate thermoelectric current. Consequently, additional technical effort and therefore also financial expense is required to generate the said thermoelectric current.

This is where the invention wants to provide a remedy. The invention is based on the task of making it possible to generate the generation of thermoelectric current without additional apparatuses and generators. According to the invention, this task is accomplished by means of a thermoelectric component for generating thermoelectric current, which component is formed from at least two layers and from two metallic electrical contacts, wherein the layers have different mixtures and their mixtures contain limestone and quartz sand.

With the invention, thermoelectric component for generating thermoelectric current is created, in which voltage occurs as a result of the temperature difference between the individual layers, which voltage is picked up using metal contacts on the free surfaces of the thermoelectric component. Furthermore, the invention creates the possibility of generating thermoelectric current without having to affix additional apparatuses for this purpose. Instead, the component according to the invention offers the possibility of creating a building from a plurality of components according to the invention, or paneling it, and thereby generating current directly. It is therefore no longer necessary to affix additional apparatuses for generating the thermoelectric current on an existing building. This offers the possibility of significant cost savings, so that use of the thermoelectric current is possible at lower financial expenditure, over an entire surface area.

In an embodiment of the invention, the layers and the cloth are connected with one another in sandwich-like manner. In this way, it is guaranteed that a large-area thermoelectric component can be produced.

Application sectors of the thermoelectric components according to the invention are dependent on the thickness of the metallic electrical contacts and on the thickness of the mixture layers. In other words, the thermoelectric components according to the invention can be produced, among other things, as facade paneling, as wall elements, or even as wallpaper.

The task is furthermore accomplished, according to the invention, by a method for the production of a thermoelectric component, in which a first mixture for the first layer is produced from quartz sand powder, limestone, alumina, fermite, and potassium, and a second mixture for the second layer is produced from quartz sand powder, limestone, alumina, gypsum, and sodium, the two mixtures are subsequently stirred up, in each instance, with methylcellulose and water, to form a paste-like mass, the first mixture of the first layer is thinly applied to a cloth, and the electrical contact of the minus pole is affixed to the upper layer side, which is still damp, the second mixture of the second layer is applied to the other side of the cloth, and the electrical contact of the plus pole is affixed onto it, and subsequently the component is dried.

Other further developments and embodiments of the invention are indicated in the other dependent claims. An exemplary embodiment of the invention is shown in the drawing and described in detail below. The drawing shows:

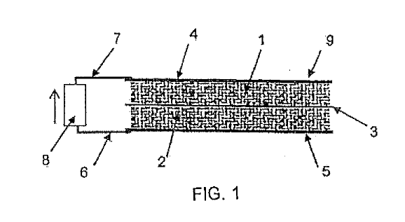

FIG. 1 the schematic representation of a thermoelectric component for generating thermoelectric current, connected to an electrical consumer.

The thermoelectric component 9 according to the invention, for generating thermoelectric current, is formed from at least two layers 1, 2 and from two metallic electrical contacts 4, 5. The layers 1, 2 have different mixtures. Their mixtures contain limestone and quartz sand. The layers 1, 2 can furthermore contain portions of alumina. In order to allow the substances required to produce the layers 1, 2 to enter into a reliable bond, these can contain methylcellulose portions.

The first layer 1 can furthermore contain termite portions, potassium portions, or potassium chloride. The second layer 2, in contrast, can have sodium portions, sodium carbonate portions, or gypsum portions.

In the exemplary embodiment, a cloth 3 is disposed between the layers 1 and 2. The layers 1 and 2 and the cloth 3 are connected with one another in sandwich-like manner. The cloth 3 demonstrates viscose portions. In a modification of the exemplary embodiment, the cloth 3 can also contain portions of wool, cotton, and cellulose, depending on the application case.

Metallic electrical contacts 4, 5, to which electrical lines 6, 7 are connected, are disposed on the layers 1 and 2. The layers 1 and 2 are electrically connected with one another by way of the electrical lines 6 and 7. A consumer 8 is disposed between the lines 6, 7.

The electrical contact 4 forms the minus pole, the electrical contact 5 forms the plus pole of the component 9. In the exemplary embodiment, the electrical contact 4 is formed by an aluminum plate. In a modification of the exemplary embodiment, the electrical contact 4 can also be formed as a tin plate, aluminum foil, tin foil, or steel sheet. The electrical contact 5 is formed from a copper foil. However, it can also be formed from brass, copper foil, bronze, or constantan.

By means of heating the layer 1 that forms the warm side, with a simultaneously unchanged or even a decreasing temperature, as the result of additional cooling, of the layer 2 that forms the cold side, regrouping of the electrons takes place. Consequently, the electrons on the hot side have a greater motion energy than the electrons on the cold side of the component 9. The greater motion energy brings about the result that the hot electrons distribute more strongly in the component 9 than the cold ones. In this manner, disequilibrium occurs, because the electron density on the cold side increases. This happens until the electrical voltage that has built up ensures that an equally great current of cold electrons flows to the hot side.

Because of the insulating effect of the cloth 3, no heat transport from the layer 1 in the direction of the layer 2 takes place at the same time. As a result, the temperature in the layer 2 is not influenced by the heat radiation onto the layer 1. This is very advantageous, because the temperature difference between the layers 1 and 2 has a significant influence on the performance capacity in generating current in the component according to the invention.

The thermoelectric component 9 according to the invention is produced according to the following steps.

In the preparatory phase, methylcellulose (wallpaper glue) is stirred up with water, in a clean bowl, until a viscous, sticky mass is formed. In a second bowl, the first mixture for the first layer 1, composed of 45% quartz sand powder, 50% limestone, 4% alumina, 0.5% fermite, and 0.5% potassium, together, is gradually mixed with the wallpaper glue, until a dough-like mass forms. Potassium chloride can be used as a substitute for potassium.

In a third bowl, the second mixture for the second layer 2, composed of 45% quartz sand powder, 50% limestone, 4% alumina, 0.5% gypsum, and 0.5% sodium, together, is gradually mixed with the wallpaper glue, until a dough-like mass forms. Sodium carbonate (bicarbonate of soda) can be used as a substitute for sodium. It should be noted that the proportions of the mixtures are weight proportions.

In the second work step, the first mixture of the first layer 1 is thinly applied to a thin cloth 3. A metal plate or metal foil is affixed to the top layer side, which is still damp, as the electrical contact 4 of the minus pole. Aside from aluminum, sheet steel and tin are also suitable as a minus pole contact.

The second mixture of the second layer 2 is thinly applied to the other side of the cloth 3, and the metal plate or metal foil of copper, bronze, brass or constantan is affixed to that as the electrical contact 5 of the plus pole. The electrical lines 6, 7 are affixed to the two metallic electrical contacts 4, 5.

Using the electrical lines 6, 7, the individual thermoelectric components can be switched in series or parallel with one another. The electrical lines 6, 7 can then be connected with an electrical consumer 8.

After the drying time of 1 to 2 days, the thermoelectric component 9 is coated with insulation varnish or synthetic resin to make it watertight, depending on the area of application.

1. Thermoelectric component (9) for generating thermoelectric current, which is formed from at least two layers (1, 2) and from two metallic electrical contacts (4, 5), wherein the layers (1, 2) have different mixtures and their mixtures contain limestone and quartz sand, whereby a cloth (3) is disposed between the layers (1, 2).

2. Thermoelectric component according to claim 1, wherein the layers (1, 2) contain alumina.

3. Thermoelectric component according to claim 1, wherein the layers (1, 2) contain methylcellulose portions.

4. Thermoelectric component according to claim 1, wherein the first layer (1) contains fermite portions.

5. Thermoelectric component according to claim 1, wherein the first layer (1) contains potassium portions.

6. Thermoelectric component according to claim 1, wherein the first layer (1) contains potassium chloride portions.

7. Thermoelectric component according to claim 1, wherein the second layer (2) contains sodium portions.

8. Thermoelectric component according to claim 1, wherein the second layer (2) contains sodium carbonate portions.

9. Thermoelectric component according to claim 1, wherein the second layer (2) contains gypsum portions.

10. (canceled)

11. Thermoelectric component according to claim 1, wherein the layers (1, 2) and the cloth (3) are connected with one another in sandwich-like manner.

12. Thermoelectric component according to claim 1, wherein metallic electrical contacts (4, 5) are disposed on the layers (1, 2).

13. Method for the production of a thermoelectric component, in which
a first mixture for the first layer (1) is produced from quartz sand powder, limestone, alumina, fermite, and potassium or potassium chloride,
a second mixture for the second layer (2) is produced from quartz sand powder, limestone, alumina, gypsum, and sodium, sodium carbonate, or gypsum
the two mixtures are stirred up, in each instance, with methylcellulose and water, to form a dough-like mass,
the first mixture of the first layer (1) is thinly applied to a cloth (3), and the electrical contact (4) of the minus pole is affixed to the upper layer side, which is still damp,
the second mixture of the second layer (2) is applied to the other side of the cloth (3), and the electrical contact (5) of the plus pole is affixed onto it,
and subsequently the component is dried.

14. Method according to claim 13, wherein the electrical lines (6, 7) are affixed onto the two metallic electrical contacts (4, 5).

15. Method according to claim 13, wherein the component (9) is coated to be watertight.
